(19) United States
(12) Patent Application Publication
(10) Pub. No.: US 2025/0147332 A1
(43) Pub. Date: May 8, 2025

(54) DETACHABLY SUPPORTING MECHANISM AND RETICLE POD WITH THE SAME

(71) Applicant: GUDENG PRECISION INDUSTRIAL CO., LTD., New Taipei (TW)

(72) Inventors: Ming-Chien Chiu, New Taipei (TW); Chia-Ho Chuang, New Taipei (TW); Pin-Cheng Chen, New Taipei (TW); Yen-Cheng Tu, New Taipei (TW); Hsin-Min Hsueh, New Taipei (TW)

(21) Appl. No.: 18/916,807

(22) Filed: Oct. 16, 2024

Related U.S. Application Data
(60) Provisional application No. 63/546,941, filed on Nov. 2, 2023.

(51) Int. Cl. G02B 27/32

(52) U.S. Cl. CPC G02B 27/32

(57) ABSTRACT

Provided is a reticle pod with a detachable supporting mechanism, which is suitable for a dual pod, including an outer pod and an inner pod received therein, the inner pod including: a base, and at least a supporting mechanism, mounted on the base. The supporting mechanism includes: a supporting assembly, connected to a mounting interface of the base, the supporting assembly includes a seat, at least one limiting post, and a mounting hole, the at least one limiting post connects to the seat, the mounting hole penetrates the base and not a circular hole; and a supporting element, having a matching structure, so that the supporting element detachably received in the mounting hole.

### CROSS-REFERENCE TO RELATED APPLICATIONS

This application claims priority to U.S. Provisional Patent Application No. 63/546,941 filed in U.S. on Nov. 2, 2023 the entire contents of which are hereby incorporated by reference.

### BACKGROUND OF THE INVENTION

### Field of the Invention

The present disclosure relates to a support mechanism of a reticle pod, and more particularly to a support mechanism having a detachable supporting structure.

### Description of the Prior Art

A conventional extreme ultraviolet (EUV) reticle pod features a support mechanism for supporting a reticle. The support mechanism comprises a support component and a position-limiting post. The support component carries the reticle and is in contact therewith. The position-limiting post and the support component are integrally formed. When the support mechanism is fitted to the baseplate of the inner pod of the reticle pod, not only is the fixation achieved with a screw, but a knurled pin is also riveted into the position-limiting post to reinforce the fixation and preclude loosening. Owing to the interference between the knurled pin and the interior of the position-limiting post, changing the conventional support structure entails destroying the position-limiting post, then removing the screw, finally knocking the knurled pin out.

However, in practice, only the support component is in contact with the reticle, and the position-limiting post is not in contact with the reticle in normal situation in order to prevent abnormal operation from wrongly damaging parts and components of the reticle accidentally. Thus, only the support component is a consumable, and the position-limiting post need not be changed. However, owing to the existing design, changing the support component entails changing the position-limiting post and the support component to the detriment of the efficient use of materials, cost effectiveness, and ease of removal.

### SUMMARY OF THE INVENTION

In view of the aforesaid drawbacks of the prior art, the disclosure provides a detachable supporting structure conducive to the simplification of a process of detaching a support mechanism and the reduction of a waste of materials and cost. Furthermore, the support mechanism comprises a supporting component made of a wear-resistant material as needed to extend service life.

The disclosure provides a reticle pod, adapted for a dual pod, comprising an outer pod and an inner pod received therein, the inner pod comprising: a baseplate and at least one support mechanism disposed on the baseplate; the support mechanism comprising: a supporting assembly connected to an installation interface of the baseplate and comprising a base, at least one position-limiting post, and an installation hole, the at least one position-limiting post being connected to the base, with the installation hole penetrating the base and not being round in shape; and a supporting component having a matching structure adapted to match the installation hole and allow the supporting component to be detachably received in the installation hole.

In a specific embodiment, the matching structure has at least one anti-self-rotation feature for abutting against an edge defining the installation hole when the supporting component is disposed at the installation hole.

In a specific embodiment, a thickness of the anti-self-rotation feature equals or approximates to a thickness of the base.

In a specific embodiment, the supporting component comprises a contact portion, a neck portion and a bottom portion, the contact portion and the bottom portion connected by neck portion and the neck portion having the at least one anti-self-rotation feature.

In a specific embodiment, the supporting component comprises a contact portion, a neck portion and a bottom portion, the bottom portion having at least one protrusion protruding outward therefrom, at least one notch is formed in the installation hole, corresponding in shape to the at least one protrusion, and extending outward from the edge defining the installation hole.

In a specific embodiment, the neck portion has at least one anti-self-rotation feature, and the installation hole has at least one positioning convex portion protruding inward from the edge defining the installation hole and abutting against the at least one anti-self-rotation feature to prevent the supporting component from rotating relative to the supporting assembly.

In a specific embodiment, the at least one anti-self-rotation feature is an abutting convex portion extending outward from a surface of the neck portion, the abutting convex portion of the neck portion misaligns with the at least one protrusion of the bottom portion in perpendicular directions respectively.

In a specific embodiment, the bottom portion has at least one depression sinking inward in a radial direction to a surface of the bottom portion to allow the bottom portion to avoid the positioning convex portion of the installation hole as soon as the supporting component is placed in the installation hole.

In a specific embodiment, the at least one depression and the at least one protrusion of the bottom portion adjoin each other.

In a specific embodiment, the supporting component comprises a fixing hole formed at the bottom portion and the neck portion, and is mounted after being rotated to a positioning position at which the abutting convex portion and the positioning convex portion abut against each other through coordination between a fixing element and the fixing hole.

In a specific embodiment, an upper surface of the base in contact with a lower surface of the contact portion and a lower surface of the base in contact with an upper surface of the bottom portion when the supporting component is located at the positioning position.

In a specific embodiment, the supporting component and the supporting assembly are made of different materials.

In a specific embodiment, the supporting component is made of a material with a glass transition temperature equal to or greater than 200° C. (392° F.).

### BRIEF DESCRIPTION OF THE DRAWINGS

The disclosure is depicted by drawings, illustrated by non-restrictive, non-exhaustive embodiments, and described below. The drawings are not drawn to scale but are aimed at disclosing the structural features and principles of the disclosure.

FIG. 1 is a perspective view of a baseplate of an inner pod comprising a support mechanism according to an embodiment of the disclosure.

FIG. 2 is an enlarged, exploded view of the support mechanism restricted to circle A shown in FIG. 1 according to an embodiment of the disclosure.

FIG. 3 is a partial, enlarged, perspective view of how to replace the support mechanism with a supporting component according to an embodiment of the disclosure.

FIG. 4A is a bottom view of the supporting component according to an embodiment of the disclosure.

FIG. 4B is a front view of the supporting component according to an embodiment of the disclosure.

FIG. 4C is a perspective view of the supporting component according to an embodiment of the disclosure.

FIG. 5A is a bottom view of a supporting assembly according to an embodiment of the disclosure.

FIG. 5B is a front view of the supporting assembly according to an embodiment of the disclosure.

FIG. 6A is a perspective view of the support mechanism when the supporting component is located at a positioning position according to an embodiment of the disclosure.

FIG. 6B is a perspective view, taken from another angle, of the support mechanism when the supporting component is not located at a positioning position according to an embodiment of the disclosure.

FIG. 7A is a perspective view of the support mechanism when the supporting component is located at a positioning position according to an embodiment of the disclosure.

FIG. 7B is a perspective view, taken from another angle, of the support mechanism when the supporting component is located at a positioning position according to an embodiment of the disclosure.

FIG. 8A is a cross-sectional view taken along plane B in FIG. 6A.

FIG. 8B is a cross-sectional view taken along plane C in FIG. 7A.

FIG. 9 is a partial, enlarged, exploded view of the support mechanism according to the second embodiment of the disclosure.

FIG. 10 is a partial, enlarged, perspective view of how to replace the support mechanism with the supporting component according to the second embodiment of the disclosure.

FIG. 11A is a lateral view of the supporting component according to the second embodiment of the disclosure.

FIG. 11B is a top view of the supporting component according to the second embodiment of the disclosure.

FIG. 12A is a lateral view of the supporting assembly according to the second embodiment of the disclosure.

FIG. 12B is a top view of the supporting assembly according to the second embodiment of the disclosure.

### DETAILED DESCRIPTION OF THE EMBODIMENTS

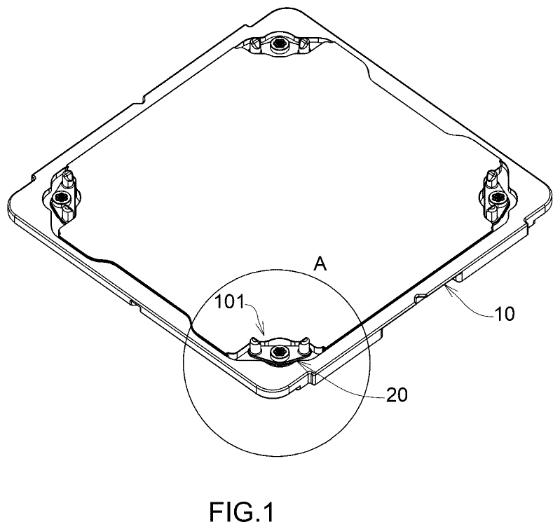

Referring to FIG. 1, the disclosure provides a reticle pod having a detachable support mechanism, adapting for a dual pod, comprising an outer pod and an inner pod received therein. The inner pod comprises a baseplate 10, a cover (not shown), and a support mechanism 20. The support mechanism 20 is connected to an installation interface 101 of the baseplate 10 and adapted to carry a reticle.

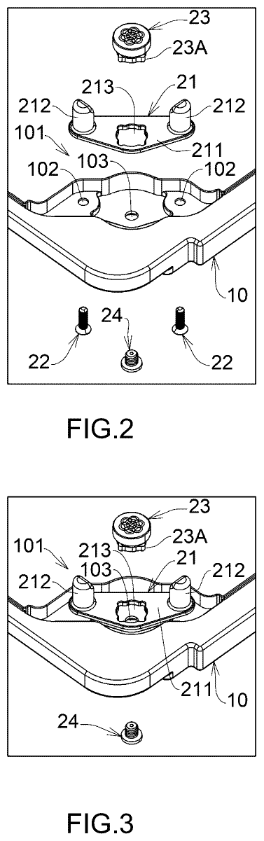

Referring to FIG. 2, there is shown an enlarged, exploded view of the support mechanism restricted to circle A shown in FIG. 1 according to an embodiment of the disclosure. In the first embodiment of the disclosure, the detachable support mechanism 20 comprises a supporting assembly 21 and a supporting component 23. The supporting assembly 21 is disposed on the installation interface 101 of the baseplate 10. The supporting component 23 has a matching structure 23A for matching an installation hole 213 of the supporting assembly 21 to allow the supporting component 23 to be detachably received in the installation hole 213 of the supporting assembly 21.

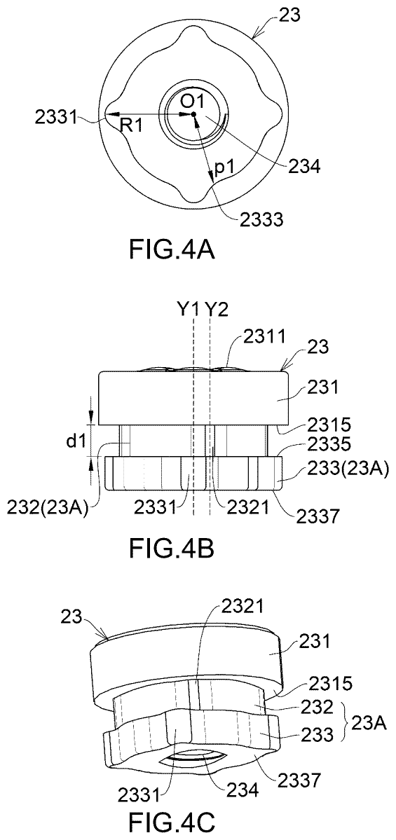

Referring to FIG. 4A through FIG. 4C, the supporting component 23 has a contact portion 231, a fixing hole 234, and the matching structure 23A. The contact portion 231 enables a user to grip or rotate the supporting component 23. The fixing hole 234 penetrates the matching structure 23A. Referring to FIG. 3, the matching structure 23A penetrates the installation hole 213 and partially abuts against the installation hole 213 to allow the supporting component 23 to be received in the installation hole 213. In this embodiment, the matching structure 23A comprises a neck portion 232 and a bottom portion 233. The contact portion 231 and the bottom portion 233 are connected by the neck portion 232. The fixing hole 234 is disposed in the bottom portion 233 and the neck portion 232. In this embodiment, the fixing hole 234 starts from a lower surface 2337 of the bottom portion 233 and fully or partially extends to the neck portion 232. Preferably, an upper surface of the contact portion 231 can be in direct contact with a reticle, whereas the neck portion 232 extends from a lower surface 2315 of the contact portion 231 and extends from an upper surface 2335 of the bottom portion 233. Preferably, an upper surface of the contact portion 231 has a plurality of contact bulges 2311 conducive to the reduction of the contact area between a reticle and the supporting component 23 when the reticle is carried by the reticle pod.

The peripheral edge of the bottom portion 233 has at least one protrusion 2331 and at least one depression 2333. The protrusion 2331 protrudes outward in the radial direction to the surface of the bottom portion 233. The depression 2333 sinks inward in the radial direction to the surface of the bottom portion 233. The at least one protrusion 2331 and the at least one depression 2333 adjoin each other. Preferably, the bottom portion 233 has a center O1, whereas a distance R1 between the protrusion 2331 and the center O1 is greater than a distance p1 between the depression 2333 and the center O1. In an embodiment of the disclosure, the edge of the bottom portion 233 has four protrusions 2331 and four depressions 2333.

Referring to FIG. 4B and FIG. 4C, the neck portion 232 has at least one abutting convex portion 2321 (also known as “anti-self-rotation feature”) protruding outward from the surface of the neck portion 232 and in the radial direction. From a front-view perspective, the neck portion 232 has a thickness d1. The thickness d1 is also defined as the perpendicular distance between the lower surface 2315 of the contact portion 231 and the upper surface 2335 of the bottom portion 233. The longest distance R1 between the protrusion 2331 and the center O1 of the bottom portion 233 is defined with perpendicular direction Y1. The shortest distance p1 between the abutting convex portion 2321 and the center O1 of the bottom portion 233 is defined with perpendicular direction Y2. The protrusion 2331 misalign with the abutting convex portion 2321 in perpendicular directions respectively, and thus perpendicular direction Y1 and perpendicular direction Y2 are parallel but do not overlap.

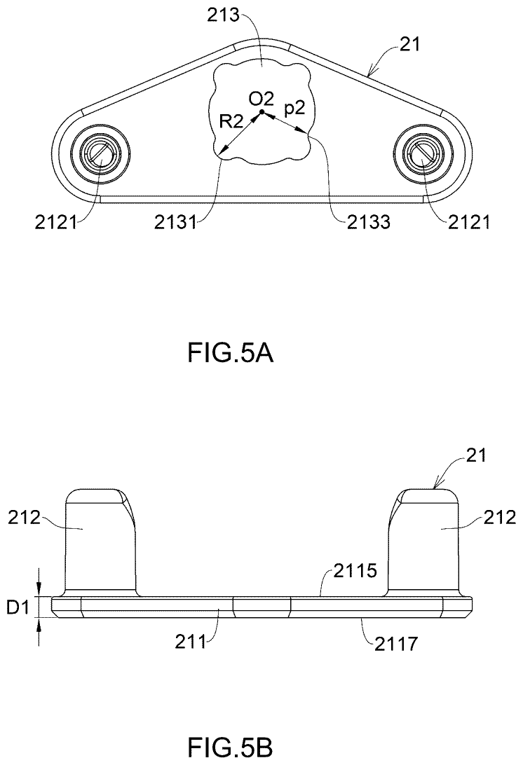

Referring to FIG. 5A and FIG. 5B, the supporting assembly 21 has a base 211, at least one position-limiting post 212, and the installation hole 213. The at least one position-limiting post 212 is connected to the base 211. The at least one position-limiting post 212 has therein a fixing hole 2121. The installation hole 213 penetrates the base 211 and is not round in shape. The matching structure 23A of the supporting component 23 corresponds in shape to the installation hole 213, allowing the supporting component 23 to be detachably mounted in place inside the installation hole 213. From a front-view perspective of the supporting assembly 21, the base 211 has a thickness D1, and the thickness D1 substantially equals or approximates to the thickness d1 of the neck portion 232 of the supporting component 23.

The edge defining the installation hole 213 has at least one notch 2131 and at least one positioning convex portion 2133. The notch 2131 extends outward in the radial direction of the installation hole 213. The positioning convex portion 2133 sinks inward in the radial direction of the installation hole 213. The at least one notch 2131 and the at least one positioning convex portion 2133 adjoin each other. When fitting the supporting component 23 to the supporting assembly 21, the notch 2131 can avoid the matching structure 23A of the supporting component 23 and causes the positioning convex portion 2133 to abut against the matching structure 23A of the supporting component 23 for the sake of mutual position, precluding unnecessary self-rotation of the supporting component 23 during the installation process.

In this embodiment, when the supporting component 23 is fitted to the supporting assembly 21, the protrusions 2331 of the supporting component 23 avoid the supporting assembly 21, and the depressions 2333 of the supporting component 23 avoid the positioning convex portion 2133. When the supporting component 23 is fitted to the supporting assembly 21, the positioning convex portion 2133 matches and engages with the abutting convex portion 2321 of the supporting component 23. In this embodiment, the installation hole 213 has a center O2, and a distance R2 between the notch 2131 and the center O2 is greater than a distance p2 between the positioning convex portion 2133 and the center O2. Preferably, the notch 2131 corresponds in shape to the protrusions 2331, and the positioning convex portion 2133 corresponds in shape to the depressions 2333. Preferably, the distance R2 between the notch 2131 and the center O2 is greater than or equal to the distance R1 between the protrusion 2331 and the center O1. In this embodiment, the edge defining the installation hole 213 connects to four notches 2131 and four positioning convex portions 2133.

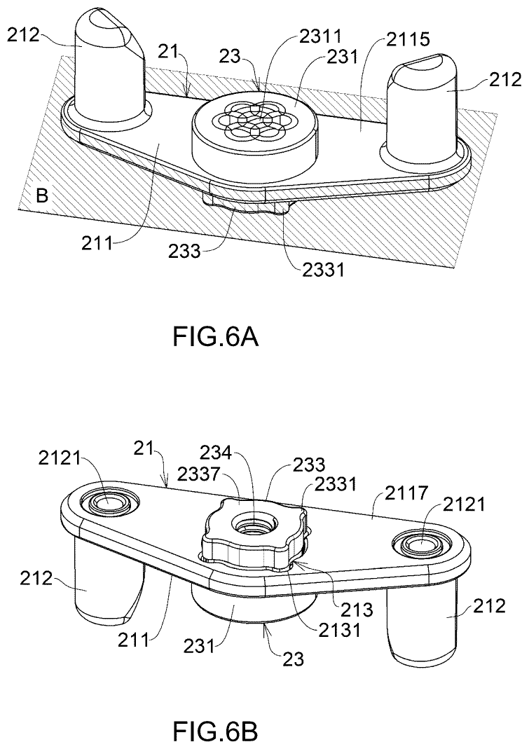

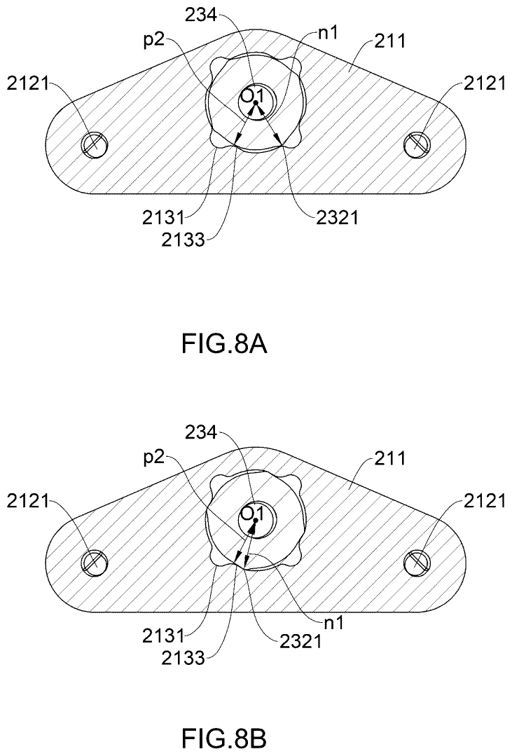

Referring to FIG. 6A and FIG. 6B, the diagrams depict the position of the supporting component 23 and the position of the supporting assembly 21 precisely but omit the baseplate 10. When the supporting component 23 is received in the supporting assembly 21, the user can grip directly or use a robotic arm to grip the contact portion 231 of the supporting component 23 to align the protrusions 2331 of the supporting component 23 with the notches 2131 of the installation hole 213 and insert the supporting component 23 into the installation hole 213 until the lower surface of the contact portion 231 comes into contact with the upper surface 2115 of the base 211. At this point in time, the contact portion 231 is located above the upper surface 2115 of the base 211, and the bottom portion 233 is located below the lower surface 2117 of the base 211, allowing the neck portion 232 to be received in the installation hole 213. Referring to FIG. 8A, there is shown a cross-sectional view taken along plane B in FIG. 6A. At this point in time, the abutting convex portion 2321 and the positioning convex portion 2133 are not in contact with each other.

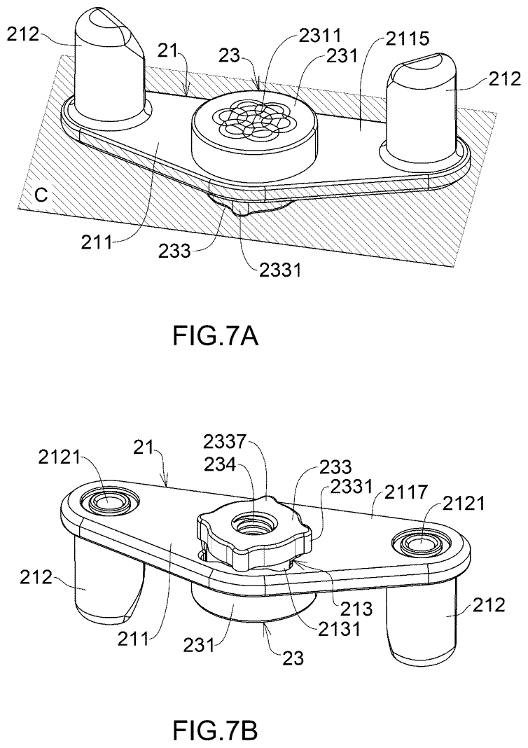

Referring to FIG. 7A and FIG. 7B, after the supporting component 23 has been rotated in a direction, each of the protrusions 2331 misaligns with a corresponding one of the notches 2131 in perpendicular directions respectively such that the upper surface of the bottom portion 233 comes into contact with the lower surface of the base 211, preventing deviation of the supporting component 23 from the perpendicular directions. Referring to FIG. 8B, there is shown a cross-sectional view taken along plane C in FIG. 7A. The supporting component 23 is rotated until the abutting convex portion 2321 and the positioning convex portion 2133 abut against each other to cause the supporting component 23 to be located at the positioning position. Then, an installation element 24 fastens the supporting component 23 in place from under the baseplate 10 to allow the supporting component 23 to be mounted in place inside the supporting assembly 21 disposed on the baseplate 10, finishing the installation of the support mechanism 20. Since the abutting convex portion 2321 and the positioning convex portion 2133 abut against each other, the supporting component 23 cannot rotate relative to the supporting assembly 21 while the supporting component 23 is being fastened in place with the installation element 24. Preferably, a distance t1 between the center O1 of the supporting component 23 and the abutting convex portion 2321 is greater than the distance p2 between the center O1 of the supporting component 23 and the positioning convex portions 2133 such that the positioning convex portions 2133 of the installation hole 213 can abut against the supporting component 23 to prevent the supporting component 23 from rotating relative to the supporting assembly 21. In this embodiment, the installation element 24 is a screw, and the fixing hole 234 is a threaded hole corresponding to the screw. The direction in which supporting component 23 is rotated to let the abutting convex portion 2321 and the positioning convex portions 2133 abut against each other is the same as the direction in which the installation element 24 fastens the supporting component 23 in place; thus, when the supporting component 23 is fastened in place, the abutting convex portion 2321 and the positioning convex portion 2133 are in contact with each other continuously, precluding unnecessary self-rotation of the supporting component 23 during the fastening process to enhance installation efficiency.

The process flow of mounting the detachable support mechanism on an installation interface of a baseplate according to the first embodiment of the disclosure is described below. First, referring to FIG. 2 and FIG. 5A, fixing the supporting assembly 21 to the fixing hole 2121 in the position-limiting post 212 by passing a fixing element 22 through a through hole 102 of the baseplate 10. The fixing element 22 is riveted to the position-limiting post 212 with a knurled pin or fastened to the position-limiting post 212 with a screw.

Then, referring to FIG. 6A and FIG. 6B, the protrusions 2331 of the supporting component 23 are aligned with the notches 2131 of the installation hole 213 to allow the supporting component 23 to be inserted into the installation hole 213 until the lower surface 2315 of the contact portion 231 and the upper surface 2115 of the base 211 are in contact with each other.

Next, referring to FIG. 7A and FIG. 7B, the supporting component 23 is rotated in a direction such that each of the protrusions 2331 of the supporting component 23 misaligns with a corresponding one of the notches 2131 of the installation hole 213 in perpendicular directions respectively, allowing the upper surface 2335 of the bottom portion 233 and the lower surface 2117 of the base 211 to be in contact with each other. Referring to FIG. 8B, the supporting component 23 is rotated until the positioning convex portions 2133 comes into contact with the abutting convex portion 2321, allowing the supporting component 23 to reach the positioning position.

Finally, the installation element 24 passes through a through hole 103 of the baseplate 10 from below to fasten the supporting component 23 in place, finishing the installation of the support mechanism 20. When the supporting component 23 is disposed at the installation hole 213, the abutting convex portion 2321 continuously abuts against the positioning convex portions 2133 of the installation hole 213, precluding unnecessary self-rotation of the supporting component 23 relative to the supporting assembly 21 during the installation process.

The replacement of the supporting component 23 entails removing the installation element 24, then rotating the supporting component 23 until the protrusions 2331 of the supporting component 23 align with the notches 2131 of the installation hole 213 respectively to take the supporting component 23 out of the installation hole 213, and finally repeating the aforesaid steps.

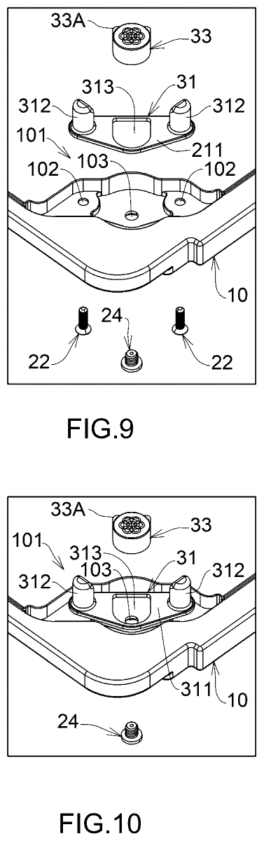

The support mechanism in the second embodiment of the disclosure as shown in FIG. 9 is distinguished from its counterpart in the first embodiment of the disclosure in terms of the structural features of a supporting component 33 and a supporting assembly 31 of the support mechanism in the second embodiment of the disclosure.

The detachable support mechanism in the second embodiment of the disclosure comprises the supporting assembly 31 and the supporting component 33. The supporting assembly 31 is disposed on the installation interface 101 of the baseplate 10. The supporting component 33 is detachably mounted on the supporting assembly 31.

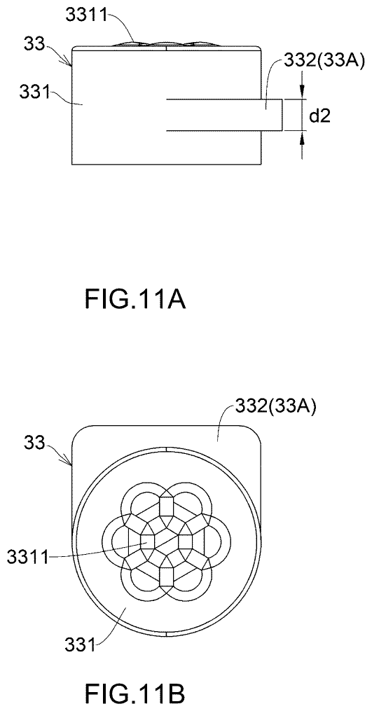

Referring to FIGS. 11A and 11B, the supporting component 33 comprises a body 331, matching structure 33A, and fixing hole (not shown). The body 331 is substantially cylindrical and has a plurality of contact bulges 3311 disposed on its upper surface to reduce the contact area between the supporting component 33 and a reticle carried by the reticle pod. The matching structure 33A matches an installation hole 313 of the supporting assembly 31 to allow the supporting component 33 to be received in the installation hole 313 of the supporting assembly 31. In this embodiment, the matching structure 33A has an anti-self-rotation feature 332 protruding outward from the body 331. From a lateral-view perspective, the anti-self-rotation feature 332 has a thickness d2. The fixing hole is disposed inside the body 331 and partially penetrates the body 331.

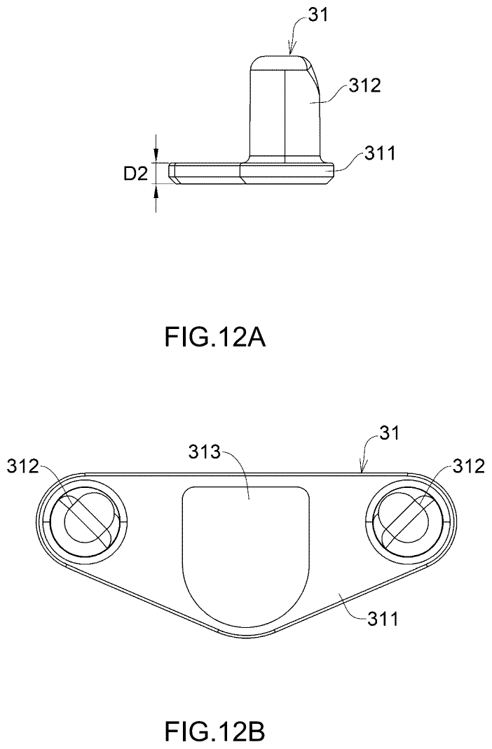

Referring to FIGS. 12A and 12B, the supporting assembly 31 has a base 311, at least one position-limiting post 312, and an installation hole 313. The at least one position-limiting post 312 is connected to the base 311. The at least one position-limiting post 312 has therein a fixing hole (equivalent to the fixing hole 2121 in the first embodiment). The installation hole 213 penetrates the base 311 and is not round in shape. The cross section of the anti-self-rotation feature 332 corresponds in shape to the installation hole 313 such that the supporting component 33 can be received in the installation hole 313 to abut against the installation hole 313, precluding self-rotation of the supporting component 33. From a front-view perspective of the supporting assembly 31, the base 311 has a thickness D2, and the thickness D2 substantially equals or approximates to the thickness d2 of the anti-self-rotation feature 332 of the supporting component 33.

The process flow of mounting the detachable support mechanism on the baseplate 10 according to the second embodiment of the disclosure is described below. Referring to FIG. 10, first, fixing the supporting assembly 31 to the fixing hole 2121 in the position-limiting post 312 by passing the fixing element 22 through the through hole 102 of the baseplate. The fixing element 22 is riveted to the position-limiting post 312 with a knurled pin or fastened to the position-limiting post 312 with a screw.

Then, the user can grip directly or use a robotic arm to grip and align the matching structure 33A of the supporting component 33 with the installation hole 313 and insert the matching structure 33A of the supporting component 33 into the installation hole 313. Next, the supporting component 33 is mounted in place by passing the installation element 24 through the through hole 103 of the baseplate 10 from below, finishing the installation of the support mechanism. The cross section of the anti-self-rotation feature 332 corresponds in shape to the installation hole 313; thus, when the supporting component 33 is disposed at the installation hole 313, the anti-self-rotation feature 332 continuously abuts against the edge defining the installation hole 313, precluding self-rotation of the supporting component 33 relative to the supporting assembly 31 during the installation process.

The replacement of the supporting component 33 entails removing the installation element 24 to remove the supporting component 33 perpendicularly and then repeating the aforesaid steps. After being fixed to the baseplate 10, the supporting assembly 31 need not be detached and replaced, preventing a waste of materials and cost.

According to the first embodiment and the second embodiment of the disclosure, the detachable support mechanism benefits from the detachable design of the supporting components 23, 33 and the supporting assemblies 21, 31 to not only be capable of performing quick detachment and replacement but also exhibits high flexibility in terms of coordination and combination.

Preferably, the supporting assemblies 21, 31 are made of a material, or undergo surface treatment, different from the supporting components 23, 33. For instance, the supporting assemblies 21, 31 are made of a material that incurs low cost, whereas the supporting components 23, 33 are made of an appropriate material as needed. Preferably, the supporting components 23, 33 are made of a wear-resistant material, for example, a material with glass transition temperature (Tg) of 200° C. (392° F.) or above and/or a material with the capability of being insulating or performing electrostatic discharge (for example, with surface resistance ranging from 10⁴ to 10¹¹ Ω/sq) in general atmospheric environment or vacuum environment.

Preferably, in an embodiment of the disclosure, the supporting components 23, 33 are made of polyimide (Pi) and thus have enhanced wear resistance capability and extended service life. Furthermore, the supporting components 23, 33 may also be made of plastic or metal and may undergo surface treatment and surface electroplating. The supporting components 23, 33 can be electroplated with a material with glass transition temperature (Tg) of 200° C. (392° F.) or above and/or with the capability of being insulating or performing electrostatic discharge in general atmospheric environment or vacuum environment to extend the service life of the supporting components 23, 33.

The supporting components 23, 33 are made of a wear-resistant, high-performance material to effectively enhance the wear resistance capability and extend the service life of the supporting components 23, 33 and reduce the chance of a reticle being exposed to dust contamination.

What is claimed is:

1. A reticle pod, adapted for a dual pod, comprising an outer pod and an inner pod received therein, the inner pod comprising:
a baseplate and at least one support mechanism disposed on the baseplate, the support mechanism comprising:
a supporting assembly connected to an installation interface of the baseplate and comprising a base, at least one position-limiting post, and an installation hole, the at least one position-limiting post being connected to the base, the installation hole penetrating the base and not being round in shape; and
a supporting component having a matching structure adapted to match the installation hole and allow the supporting component to be detachably received in the installation hole.

2. The reticle pod of claim 1, wherein the matching structure has at least one anti-self-rotation feature for abutting against an edge defining the installation hole when the supporting component is disposed at the installation hole.

3. The reticle pod of claim 2, wherein a thickness of the anti-self-rotation feature equals or approximates to a thickness of the base.

4. The reticle pod of claim 2, wherein the supporting component comprises a contact portion, and the matching structure comprises a neck portion and a bottom portion, the contact portion and the bottom portion connected by the neck portion and the neck portion having the at least one anti-self-rotation feature.

5. The reticle pod of claim 1, wherein the supporting component comprises a contact portion, and the matching structure comprises a neck portion and a bottom portion, the bottom portion having at least one protrusion protruding outward therefrom, at least one notch is formed in the installation hole, corresponding in shape to the at least one protrusion, and extending outward from the edge defining the installation hole.

6. The reticle pod of claim 5, wherein the neck portion has at least one anti-self-rotation feature, and the installation hole has at least one positioning convex portion protruding inward from the edge defining the installation hole and abutting against the at least one anti-self-rotation feature to prevent the supporting component from rotating relative to the supporting assembly.

7. The reticle pod of claim 6, wherein the at least one anti-self-rotation feature is an abutting convex portion extending outward from a surface of the neck portion, the abutting convex portion of the neck portion misaligns with the at least one protrusion of the bottom portion in perpendicular directions respectively.

8. The reticle pod of claim 6, wherein the bottom portion has at least one depression sinking inward in a radial direction to a surface of the bottom portion to allow the bottom portion to avoid the positioning convex portion of the installation hole as soon as the supporting component is placed in the installation hole.

9. The reticle pod of claim 8, wherein the at least one depression and the at least one protrusion of the bottom portion adjoin each other.

10. The reticle pod of claim 6, wherein the supporting component comprises a fixing hole formed at the bottom portion and is fixed in place inside the installation hole after being rotated to a positioning position at which the abutting convex portion and the positioning convex portion abut against each other through coordination between a fixing element and the fixing hole.

11. The reticle pod of claim 10, wherein an upper surface of the base in contact with a lower surface of the contact portion and a lower surface of the base in contact with an upper surface of the bottom portion when the supporting component is located at the positioning position.

12. The reticle pod of claim 1, wherein the supporting component is made of a material with a glass transition temperature equal to or greater than 200° C.
